(19) United States
(12) Patent Application Publication
(10) Pub. No.: US 2008/0075857 A1
(43) Pub. Date: Mar. 27, 2008

(54) Method of facbricating buffer layer on substrate

(75) Inventors: Miin-Jang Chen, Taipei City (TW); Wen-Ching Hsu, Hsinchu City (TW); Ya-Lan Ho, Jhudong Township (TW)

Correspondence Address: BIRCH STEWART KOLASCH & BIRCH, PO BOX 747, FALLS CHURCH, VA, 22040-0747, US

(73) Assignees: MIIN-JANG CHEN; SINO-AMERICAN SILICON PRODUCTS INC.

(21) Appl. No.: 11/819,455

(22) Filed: Jun. 27, 2007

(30) Foreign Application Priority Data
Sep. 27, 2006 (TW) 095135675

(51) Int. Cl. C23C 16/40; C23C 16/00

(52) U.S. Cl. 427/255.19; 427/248.1

(57) ABSTRACT

The invention provides a method of fabricating a buffer layer on a substrate. In particular, the method, according the invention, fabricates a ZnO layer serving as the buffer layer on the substrate, such as a sapphire substrate, a Si substrate, a SiC substrate, or a glass substrate.

### BACKGROUND OF THE INVENTION

1. Field of the Invention

The invention relates to a method of fabricating a buffer layer on a substrate, and more particularly, to a method of fabricating a ZnO layer serving as the buffer layer on the substrate, which can be a sapphire substrate, a Si substrate, a SiC substrate, or a glass substrate.

2. Description of the Prior Art

Interposing a buffer layer between a substrate and an active layer (or a micro-, nano-component), such as interposing a buffer layer between a sapphire substrate and a GaN layer, is a prior art. Consequently, the buffer layer can reduce the lattice mismatch between the active layer and the substrate, the defect density of the active layer, and the difference between the thermal expansion coefficients of the active layer and the substrate.

Along with the development of diverse materials serving as buffer layers, ZnO is already popularly utilized. Reducing the surface defect by using ZnO as the buffer layer is proved by a SEM measurement. Particularly, performing the process of annealing the ZnO layer is also proved to be capable of improving the crystallization quality of the crystals. Regarding the processes of fabricating the ZnO layer serving as the buffer layer, there are methods, such as RF sputtering, molecular beam epitaxy (MBE), pulsed laser deposition (PLD) . . . etc, at the moment. Please refer to U.S. Pat. No. 6,664,565 for the related prior art.

However, through the comprehension of the prior art, we know that the property (such as shape) of the fabricated ZnO layer still has room for progress. In addition, several prior arts increase the complexity of the fabricating process. Therefore, it is clear that a fabricating method for improving the property of the ZnO layer is needed.

### SUMMARY OF THE INVENTION

A scope of the invention provides a method of fabricating a buffer layer on a substrate. In particular, the method, according the invention, fabricates a ZnO layer on the substrate, such as a sapphire substrate, a Si substrate, a SiC substrate, or a glass substrate.

According to the preferred embodiment of the invention, the method of fabricating a buffer layer on a substrate first provides a precursor of DEZn and H₂O or O₃ alternately. Then, the method performs an atomic layer deposition process at a processing temperature equal to or lower than 400° C. to form a ZnO layer on the substrate, wherein the ZnO layer serves as the buffer layer.

According to the preferred embodiment of the invention, the fabricating method performs a process of annealing the ZnO layer at a temperature ranging from 400° C. to 1200° C.

The advantage and spirit of the invention may be understood by the following recitations together with the appended drawings.

### BRIEF DESCRIPTION OF THE APPENDED DRAWINGS

FIG. 1A and FIG. 1B are sectional views for describing the method of fabricating a ZnO layer according to a preferred embodiment of the invention.

### DETAILED DESCRIPTION OF THE INVENTION

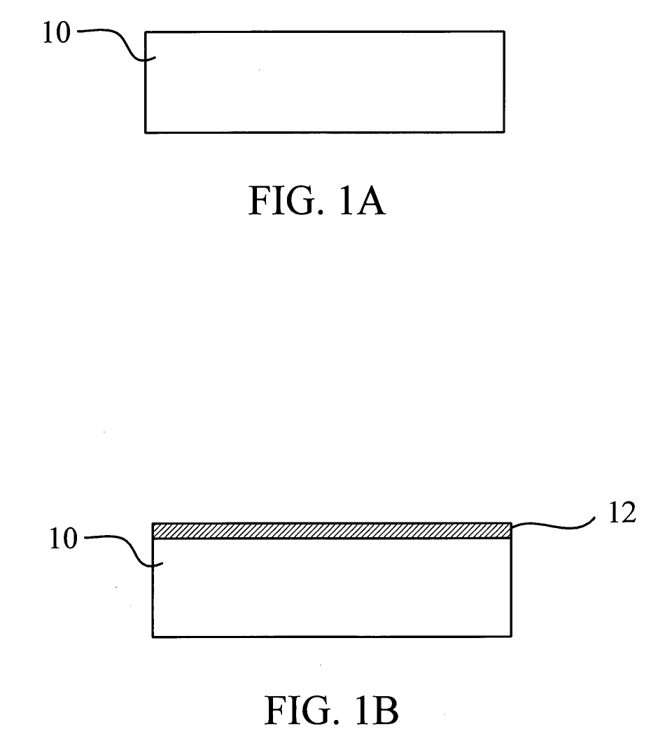

The invention provides a method of fabricating a buffer layer on a substrate. Particularly, the method of the invention can more precisely control the thickness of the fabricated buffer layer, reduce the defect density, and lower the deposition temperature. Please refer to FIG. 1A and FIG. 1B; those figures are sectional views for describing the method of fabricating the buffer layer according to the preferred embodiment of the invention. Detailed description of the method according to the preferred embodiment of the invention will be described.

First of all, as shown in FIG. 1A, the method according to the preferred embodiment of the invention is to set a prepared substrate 10 in a reaction chamber designed for performing an atomic layer deposition process.

In an embodiment, the substrate 10 can be a sapphire substrate, a Si substrate, a SiC substrate, or a glass substrate.

Then, the method according to the preferred embodiment of the invention provides a precursor of DEZn and H₂O or O₃ alternately, wherein DEZn is the source of Zn, and H₂O or O₃ is the source of O. Afterward, an atomic layer deposition process is performed at a processing temperature equal to or lower than 400° C. to form a ZnO layer 12 on the substrate 10. As shown in FIG. 1A, the ZnO layer 12 serves as the buffer layer.

In an embodiment, an atomic layer deposition cycle includes four reaction steps of:
1. Using a carrier gas to carry H₂O molecules into the reaction chamber, thereby the H₂O molecules are absorbed on a surface of the substrate to form a layer of OH radicals, where the exposure period is 0.1 second;
2. Using a carrier gas to purge the H₂O molecules not absorbed on the surface of the substrate, where the purge time is 5 seconds;
3. Using a carrier gas to carry DEZn molecules into the reaction chamber, thereby the DEZn molecules react with the OH radicals absorbed on the surface of the substrate to form one monolayer of ZnO, wherein a by-product is organic molecules, where the exposure period is 0.1 second; and
4. Using a carrier gas to purge the residual DEZn molecules and the by-product due to the reaction, where the purge time is 5 seconds.

In the aforesaid embodiment, the carrier gas can be highly pure argon gas or nitrogen gas. The above four steps is called an atomic layer deposition cycle. An atomic layer deposition cycle grows a thin film with a thickness of a single atomic layer on the entire surface of the substrate; the characteristic is named “self-limiting”, and the characteristic allows the precision of the thickness control of the atomic layer deposition to be one monolayer. Therefore, the thickness of the ZnO buffer layer can be precisely controlled by controlling the number of atomic layer deposition cycles.

In an embodiment, the processing temperature is in a range of from room temperature to 400° C. The preferred processing temperature is in a range of from 150° C. to 200° C.

In an embodiment, the ZnO layer 12 has a preferred thickness ranging from 20 nm to 500 nm.

Afterward, to further reduce the defect density and to improve surface condition, the method according to the preferred embodiment of the invention can perform a process of annealing the ZnO layer at a temperature ranging from 400° C. to 1200° C., wherein the atmosphere is introduced nitrogen gas or oxygen gas.

Obviously, comparing with the prior art, the method of fabricating the ZnO layer disclosed in the invention has the following advantages: (1) controlling the forming of the material in an atomic scale; (2) controlling the thickness of the formed buffer layer more precisely; (3) mass production with large area; (4) excellent uniformity; (5) excellent conformality; (6) pinhole-free structure; (7) small defect density; and (8) low deposition temperature.

Obviously, comparing with the prior art, the method of fabricating the ZnO layer disclosed in the invention can more precisely control the thickness of the formed buffer layer, reduce the defect density, and lower the deposition temperature. Apparently, the ZnO layer formed by the method disclosed in the invention is helpful to improve the yield rate and the property of the subsequently formed active layer (or micro-, nano-component).

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of fabricating a buffer layer on a substrate, said method comprising the steps of:
alternately providing a DEZn precursor and a H₂O precursor or an O₃ precursor; and
performing an atomic layer deposition process at a processing temperature equal to or lower than 400° C. to form a ZnO layer on the substrate, wherein the ZnO layer serves as the buffer layer.

2. The method of claim 1, wherein the processing temperature is in a range of from room temperature to 400° C.

3. The method of claim 1, wherein the substrate is one selected from the group consisting of a sapphire substrate, a Si substrate, a SiC substrate, and a glass substrate.

4. The method of claim 1, wherein the ZnO layer has a thickness ranging from 20 nm to 500 nm.

5. The method of claim 1, further comprising the step of annealing the ZnO layer at a temperature ranging from 400° C. to 1200° C.
